(19) United States
(12) Patent Application Publication
(10) Pub. No.: US 2002/0185053 A1
(43) Pub. Date: Dec. 12, 2002

(54) Method for calibrating nanotopographic measuring equipment

(76) Inventors: Lu Fei, St. Louis, MO (US); Charles Chuin-Chieh Yang, Phoenix, AZ (US)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 09/865,083

(22) Filed: May 24, 2001

(51) Int. Cl. C30B 1/00

(52) U.S. Cl. 117/2

(57) ABSTRACT

The present invention is directed to a method of calibrating a laser scanning nanotopography measuring device with a metrology standard having grown-in nanotopographic artifacts on the surface of an epitaxial layer on a silicon wafer substrate.

### BACKGROUND OF THE INVENTION

The present invention generally relates to the calibration of nanotopography measuring instruments typically used to evaluate silicon wafers used in the manufacture of electronic components. More particularly, the present invention relates to a method of preparing a metrology standard applicable for calibrating instruments used to measure the nanotopography of a semiconductor wafer.

In the production of single silicon crystals grown by the Czochralski method, polycrystalline silicon is first melted within a quartz crucible with or without dopant. After the polycrystalline silicon has melted and the temperature equilibrated, a seed crystal is dipped into the melt and subsequently extracted to form a single crystal silicon ingot while the quartz crucible is rotated. The single crystal silicon ingot is subsequently sliced into individual silicon wafers which are subjected to several processing steps including lapping/grinding, etching, and polishing to produce a finished silicon wafer having a front surface with specular gloss. In addition to polishing the front surface, many device manufacturers also request a polished back surface with a specular gloss (such wafers are commonly referred to as “double-side polished”). To prepare the finished wafer for device manufacturing, the wafer may be subjected to a chemical vapor deposition process such as an epitaxial deposition process to grow a thin layer of silicon generally between about 0.1 μm and about 200 μm thick on the front surface of the wafer such that devices can be fabricated directly on the epitaxial layer. Conventional epitaxial deposition processes are disclosed in U.S. Pat. Nos. 5,904,769 and 5,769,942.

One method of characterizing an epitaxial wafer is the variation in the surface height of the wafer generally referred to as “nanotopography”—the height variation over a small portion of the surface area of the wafer (e.g., the wafer surface may be divided into imaginary squares measuring 0.5 mm×0.5 mm, 2 mm×2 mm or 10 mm×10 mm). Nanotopography is primarily due to wafer processes such as lapping, etching, and polishing, however the variation in the epitaxial layer thickness is also significant cause. As the critical feature size of photolithography continues to decrease, silicon wafers must meet ever more stringent nanotopography standards (currently, the state of the art critical feature size is about 0.15 μm to about 0.18 μm). Variation in the nanotopography of an epitaxial silicon layer is due to thermal gradients in the wafer caused in large part by non-uniform heating of the wafer during the epitaxial deposition process. A significant cause of non-uniform heating can be the relatively large lift pin holes in the susceptor which allow the areas of the wafer directly above the lift pin holes to be heated to a different temperature than the surrounding material. The material from which the lift pins are constructed (e.g., graphite, silicon carbide and quartz) can also result in the areas of the wafer above the lift pins being heated to a different temperature. The temperature difference causes the epitaxial layer to grow at a different rate resulting in localized thickness variations (e.g., 40 nm, 60 nm, or greater) generally known as pinmarks.

In silicon wafer manufacturing settings, nanotopography is typically measured using a laser which scans a portion of the wafer surface. To ensure accurate measurement of the nanotopography with a laser surface scanner, it is desirable to calibrate the scanner using a calibration or metrology standard with a known height variation. Typically, height metrology standards are created by the controlled etching of steps into the surface of a silicon wafer (see, e.g., U.S. Pat. Nos. 6,016,684 and 6,028,008 and publication WO 99/08065). However, laser surface scanner measuring devices such as the CR83-SQM manufactured by ADE determine surface height variation by directing a laser beam at the specular surface of the wafer and measuring the position at which the laser beam strikes a quadracell detector (i.e., a circular photosensor that is divided into four quadrants) after the laser beam is reflected by the specular wafer surface. Provided the angle of incidence is constant, changes in the position of the reflected beam depend primarily on changes in the slope of the wafer surface. Thus, with this type of laser surface scanner, the nanotopographic measurement of a wafer is determined by measuring the change in slope across the wafer surface. However, because the variation in height on typical calibration standards is created by etching steps in the surface of a wafer, the surface of the wafer remains substantially parallel (i.e., the vertical change is not accompanied by a slope change). Without a change in the slope, conventional calibration standards result in an inaccurate and/or inconsistent calibration of a laser surface scanner. Inaccurate/inconsistent calibration results in, for example, the nanotopography of a wafer measured with two different laser surface scanners can vary by as much as about 15% percent.

To date, therefore, calibration standards used to calibrate laser surface scanning devices introduce errors in the nanotopography measurements. As such, a need exists in the semiconductor industry for a simple, cost effective approach to calibrate measurements of silicon wafer nanotopography.

### SUMMARY OF THE INVENTION

Among the objects of the present invention, therefore, is the provision of a method of calibrating a laser scanning nanotopography measuring device which improves the accuracy of nanotopographic measurements; the provision of a method in which a laser scanning nanotopography measuring device is calibrated against a height metrology standard without etched height variations; and the provision of a method in which a laser scanning nanotopography measuring device is calibrated against a height metrology standard for which the height variation is accompanied by a change in slope.

Briefly, therefore, the present invention is directed to a method of calibrating a laser scanning nanotopography measuring device. The method comprises growing an epitaxial silicon layer on a front surface of a silicon wafer substrate having a localized temperature nonuniformity on the front surface of the silicon wafer to create a nanotopographic artifact located at the localized temperature nonuniformity. The nanotopography of the nanotopographic artifact is measured with the laser scanning nanotopography measuring device to calibrate the laser scanning nanotopography measuring device.

Another method of calibrating a laser scanning nanotopography measuring device comprises by placing a silicon wafer substrate on a perforated susceptor in a chemical vapor deposition chamber that comprises an upper heater above the front surface of the silicon wafer substrate and a lower heater below the back surface of the silicon wafer substrate. The perforated susceptor has a surface in a generally parallel opposed relationship with the silicon wafer substrate with an opening that allows direct radiation of the back surface of the silicon wafer substrate by the lower heater. An epitaxial silicon layer is grown on the front surface of the substrate and is characterized by having a nominal thickness and a nanotopographic artifact grown into the epitaxial silicon layer above the opening in the perforated susceptor. The nanotopography of the nanotopographic artifact grown into the epitaxial silicon layer is measured with the laser scanning nanotopography measuring device to calibrate the laser scanning nanotopography measuring device.

Further, this invention is directed to a method of measuring the nanotopography of a semiconductor substrate versus that of a metrology standard. The method comprises measuring the nanotopography of the metrology standard with a laser scanner nanotopography measuring device, the metrology standard comprises a silicon wafer substrate having a front surface and a back surface and an epitaxial silicon layer grown on the front surface of the silicon wafer substrate. The epitaxial silicon layer is characterized by a nominal thickness and comprises a grown-in nanotopographic artifact characterized by a vertical variation from the nominal thickness ranging from about ±1 nm to about ±6,000 nm and a width of between about 0.1 mm to about 20 mm. The nanotopography of a portion of a surface of the semiconductor substrate is measured with the laser scanner nanotopography measuring device and compared with the nanotopography of the nanotopographic artifact of the metrology standard.

Other objects and features of this invention will be in part apparent and in part pointed out hereinafter.

### BRIEF DESCRIPTION OF THE DRAWINGS

FIG. 1 shows the cross section of a metrology standard produced in accordance with the present invention (not to scale).

FIG. 2 is a cross section of an embodiment of the perforated susceptor used in accordance with the process of the present invention (taken in the plane of line 26-26 of FIG. 3).

FIG. 3 is a top view of a wafer support device.

FIG. 4 is an epitaxial reaction chamber showing an embodiment of the perforated susceptor of FIG. 2.

FIG. 5 is a cross section of an embodiment of the perforated susceptor used in accordance with the process of the present invention.

FIG. 6 is a cross section of an embodiment of the perforated susceptor used in accordance with the process of the present invention.

Corresponding reference characters indicate corresponding parts throughout the drawings.

### DETAILED DESCRIPTION OF THE PREFERRED EMBODIMENTS

The method of the present invention is directed to a method of calibrating a laser scanning nanotopography measuring device wherein an epitaxial silicon layer is grown on a silicon wafer substrate heated in a manner that creates at least one localized temperature nonuniformity on the front surface of the silicon wafer. The localized temperature nonuniformity results in the formation of at least one nanotopographic artifact grow into the epitaxial layer. The laser scanning metrology measuring device is then calibrated with the foregoing metrology standard.

A. Substrate

The starting material for the method of the present invention is a single crystal silicon wafer substrate which has been sliced from a single crystal ingot. Growing a silicon ingot, as well as standard silicon slicing, lapping, etching, and polishing techniques, are well known in the art and disclosed, for example, in F. Shimura, Semiconductor Silicon Crystal Technology (Academic Press, 1989); and Silicon Chemical Etching, (J. Grabmaier, ed., Springer-Verlag, New York, 1982).

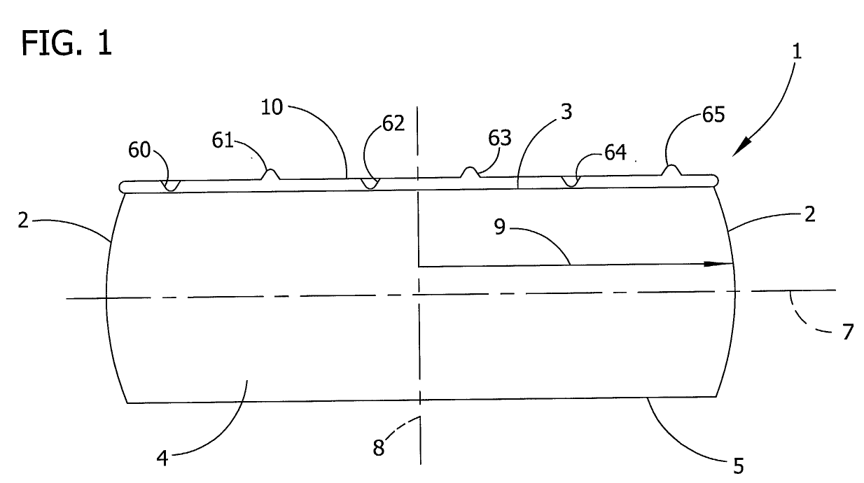

Referring to FIG. 1, the metrology standard 1 comprises a silicon wafer substrate 4 that has a central axis 8, a front surface 3, and a back surface 5 which are generally perpendicular to the central axis, a circumferential edge 2 joining the front surface 3 and the back surface 5 and a radius 9 extending from the central axis to the circumferential edge 2. Although the diameter of the wafer substrate may be of any size, the typical nominal diameter is about 200 mm or 300 mm. The wafer is double-side polished which results in a wafer which is flat (e.g., about 0.3 μm site flatness) and has a small nanotopography (e.g., about 50 nm on a 10 mm×10 mm square) compared to that of a single-side polished wafer (e.g., flatness is about 0.15 μm site flatness and nanotopography is about 80 nm on a 10 mm×10 mm square). Additionally, as long as the polishing process parameters (e.g., duration, slurry composition and pressure) are constant, the nanotopography of double-side polished wafers varies little from wafer to wafer (e.g., 5 less than about 15 nm on a 10 mm×10 mm square).

The silicon wafer substrate is further characterized by a dry surface roughness that produces a light scattering of less than about 0.5 ppm when inspected using a laser surface scanner system (e.g., a SURFSCAN SP1 available from KLA-Tencor of Malpitas, Calif., U.S.A. or a CR-80 available from ADE Optical Systems of Charlotte, N.C., U.S.A.).

Preferably, the test wafer has been cleaned and the front side of the test wafer is substantially free of light point defects (LPDs) such as particulate contamination and crystal originated pits. For example, the concentration of LPDs exceeding about 0.12 μm LSE in size on the front side of the test wafer is preferably less than about 0.1 defects/cm² (e.g., a 200 mm diameter test wafer has less than about 30 LPDs on the front side). More preferably, the concentration of LPDs exceeding about 0.12 μm LSE in size is less than about 0.06 defects/cm² (e.g., a 200 mm diameter test wafer has less than about 20 LPDs on the front side). Still more preferably, the concentration of LPDs exceeding about 0.12 μm LSE in size is less than about 0.03 defects/cm² (e.g., a 200 mm diameter test wafer has less than about 10 LPDs on the front side). The number of LPDs on the test wafer may be determined using the above-mentioned laser surface scanner systems which can currently detect LPDs as small as about 0.06 μm LSE to about 0.08 μm LSE in size. Preferably, however, the laser-based surface scanner is set to detect particles larger than about 0.12 μm LSE in size. It is well known in the art that when measuring the number of LPDs on the surface of a wafer using a laser-based surface scanner, the actual size of the LPD is not determined. Rather, the light scatter of a LPD is compared to that of a reference particle of known diameter (e.g., a latex sphere with a diameter larger than about 0.12 μm) and the LPD density is measured in terms of latex sphere equivalent (LSE) based on the reference particle setting.

The silicon wafer substrate typically has a native oxide layer on the front and back surfaces. In accordance with the method of the present invention, the epitaxial deposition process includes the removal of the native oxide layer from the front surface of the wafer prior to depositing the epitaxial layer on the front surface. The removal of the silicon oxide layer is preferably accomplished by heating the surface of the wafer in an atmosphere consisting essentially of no oxidants (most preferably, the atmosphere is oxidant-free) until the silicon oxide layer is removed from the surface. In a particularly preferred embodiment, the surface of the wafer is heated to a temperature of at least about 1100° C., and more preferably to a temperature of at least about 1150° C. This heating is preferably conducted while exposing the entire front surface of the wafer to a cleaning gas comprising a noble gas (e.g., He, Ne, or Ar), H₂, HF gas, HCl gas, or a combination thereof. More preferably, the cleaning gas comprises H₂, or a combination of H₂ and HCl. Most preferably, the cleaning gas consists essentially of H₂. It should be noted that although atmospheres containing N₂ may be used, such atmospheres are less preferred because they tend to form nitrides on the surface which may interfere with subsequent epitaxial deposition on the surface. The flow rate of the cleaning gas is typically between about 1 liter/minute and about 50 liters/minute, and preferably between about 10 liters/minute and about 20 liters/minute, for at least about 10 seconds.

Prior to or during the removal of the native oxide layer, the wafer is preferably heated at a rate which does not cause slip. More specifically, if the wafer is heated too quickly, a thermal gradient will develop which can create an internal stress sufficient to cause different planes within the wafer to shift relative to each other (i.e., slip). Below about 750° C. to about 800° C., rapid heating of the wafer is not a significant cause of slip, however, between about 800-900° C. to about 1150-1200° C. rapidly heating the wafer can cause slip. To avoid crystallographic slip, the wafer is preferably heated from about 800-900° C. to the silicon oxide removal temperature at an average rate of about 20° C./sec to about 35° C./sec. If, however, a crystallographic slip forms, the wafer may still be acceptable for use as a metrology standard because width of the slip is only that of a crystallographic plane and is typically not detected by a laser surface scanner (similar to an etched step height variation).

Following the removal of native oxide layer from the front surface of the wafer, the flow of cleaning gas is discontinued and the temperature in the reaction chamber is adjusted to between about 600° C. and about 1200° C., preferably at least about 1100° C. and more preferably at least about 1150° . The front surface of the wafer is then contacted with a silicon containing source gas to deposit the epitaxial layer onto the front surface. Preferably, the surface is contacted with the source gas less than 30 seconds after the native oxide is removed, more preferably within about 20 seconds after the native oxide layer is removed, and most preferably within about 10 seconds after the native oxide layer is removed. Waiting to initiate silicon deposition for about 10 seconds after removal of the silicon oxide layer allows the temperature of the wafer to stabilize within the desired range.

B. Epitaxial Deposition

The epitaxial deposition preferably is carried out by chemical vapor deposition. Generally speaking, chemical vapor deposition involves exposing the surface of the wafer to an atmosphere comprising silicon in an epitaxial deposition reactor, e.g., an EPI CENTURA reactor available from Applied Materials (Santa Clara, Calif., U.S.A.). In a preferred embodiment of this invention, the surface of the wafer is exposed to an atmosphere comprising a volatile gas comprising silicon (e.g., SiCl₄, SiHCl₃, SiH₂Cl₂, SiH₃Cl, or SiH₄) . The atmosphere also preferably contains a carrier gas (most preferably H₂) . Preferably, the silicon source gas is SiH₂Cl₂ or SiH₄. If SiH₂Cl₂ is used, the reactor pressure during deposition preferably is from about 500 to about 760 Torr. If, on the other hand, SiH₄ is used, the reactor pressure preferably is about 100 Torr. Most preferably, the source of silicon during the deposition is SiHCl₃. This tends to be much cheaper than other sources. In addition, an epitaxial deposition using SiHCl₃ may be conducted at atmospheric pressure. This is advantageous because no vacuum pump is required and the reactor chamber does not have to be as robust to prevent collapse. Moreover, fewer safety hazards are presented and the chance of air leaking into the reactor chamber is lessened.

During the epitaxial deposition, the temperature of the wafer surface preferably is maintained at a temperature sufficient to prevent the atmosphere comprising silicon from depositing polycrystalline silicon onto the surface. Generally, the temperature of the surface during this period preferably is at least about 900° C. More preferably, the temperature of the surface is maintained at from about 1050 to about 1150° C. Most preferably, the temperature of the surface is at least the silicon oxide removal temperature.

The rate of growth of the epitaxial layer is preferably about 3.5 μm/min to about 4.0 μm/min when the deposition is conducted under atmospheric pressure. This may be achieved, for example, by using an atmosphere consisting essentially of about 2.5 mole % SiHCl₃ and about 97.5 mole % H₂ at a temperature of about 1050° C. to 1150° C. at a flow rate of about 1 liter/minute to about 20 liters/minute.

Once an epitaxial layer having the desired nominal thickness is reached, the atmosphere comprising silicon preferably is purged from the reaction chamber with a noble gas, H₂, or a combination thereof, and more preferably with H₂ alone. Afterward, the wafer preferably is cooled to a temperature at which it can be handled without imparting damage (typically no greater than about 800-900° C., however, some apparatus can handle wafers at temperatures substantially higher than about 900° C.) and is then removed from the epitaxial deposition reactor.

Typically, an epitaxial deposition reactor comprises a chamber usually constructed of quartz, a gas inlet for allowing process gases to enter the reactor, a gas outlet for removing process gases from the reactor, an upper heater above the silicon wafer, a lower heater below the silicon wafer, a susceptor for supporting the wafer and rotatable means for supporting the susceptor and wafer. The perforated susceptor may be sized to accommodate any diameter silicon wafer including, for example, 150 mm, 200 mm and 300 mm wafers and larger.

C. Growing an Epitaxial Laver with Nanotopographic Artifacts

In accordance with the method of the present invention, nanotopographic artifacts on the surface of the epitaxial layer are formed by heating the silicon wafer substrate in a manner that produces at least one localized temperature nonuniformity on the front surface of the silicon wafer. A localized temperature nonuniformity is defined as a discreet portion of the front surface of the silicon wafer substrate in which the temperature varies from the nominal temperature of the front surface (e.g., a localized temperature nonuniformity may comprise an area as large as about 500 mm² and the difference in temperature may be as large as about ±10° C.). The localized temperature nonuniformity leads to nonuniform epitaxial silicon growth on the front surface of the silicon wafer which results in a variation in the thickness of the epitaxial layer over the area of the surface corresponding to the localized temperature nonuniformity.

The localized temperature nonuniformity is formed by varying the amount of energy from the upper and/or lower heaters delivered to the front and/or back surface of the wafer substrate. The variation in the energy being delivered to the wafer substrate is preferably accomplished by adjusting the amount of energy transmitted to the wafer substrate. The energy transmitted to the wafer may be adjusted, for example, by the selection of the materials used to construct the various components of the chemical vapor deposition reactor (e.g., quartz transmits more energy than graphite or silicon carbide). In accordance with the method of the present invention, the variation in the energy delivered to the wafer substrate is preferably accomplished by replacing a conventional susceptor with a susceptor configured in a manner that creates at least one localized temperature nonuniformity. Preferably, the susceptor comprises at least one opening, and more preferably a plurality of openings, which allow direct irradiation of the back surface of the silicon wafer substrate (“perforated susceptor”) and/or comprises materials which transmit different amounts of energy to the back surface of the silicon wafer substrate.

The perforated susceptor is preferably constructed of conventional materials such as high purity graphite with a silicon carbide or glassy carbon layer covering the graphite to reduce the amount of contaminants released into the surrounding ambient from the graphite during the high 30 temperature epitaxial deposition process. The graphite utilized to construct the wafer support device is generally at least about 99%, more preferably at least about 99.9% and most preferably at least about 99.99% pure graphite. Also, the graphite preferably contains less than about 20 ppm total metals particularly iron, molybdenum, copper, and nickel, and more preferably less than about 5 ppm total metals particularly iron, molybdenum, copper, and nickel. The silicon carbide or glassy carbon coating covering the graphite generally has a thickness of about 75 μm to about 150 μm, preferably about 100 μm to about 125 μm. Similar to the graphite, the silicon carbide or glassy carbon coating should have a total metal concentration less than about 20 ppm and preferably less than about 5 ppm.

1. Perforated Susceptor in which the Wafer Rests on an Inner Annular Ledge

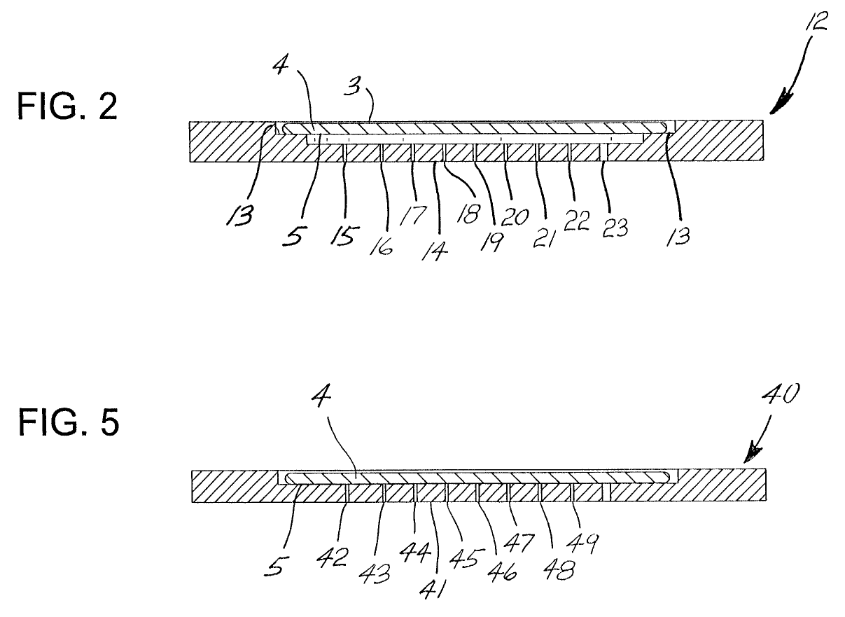

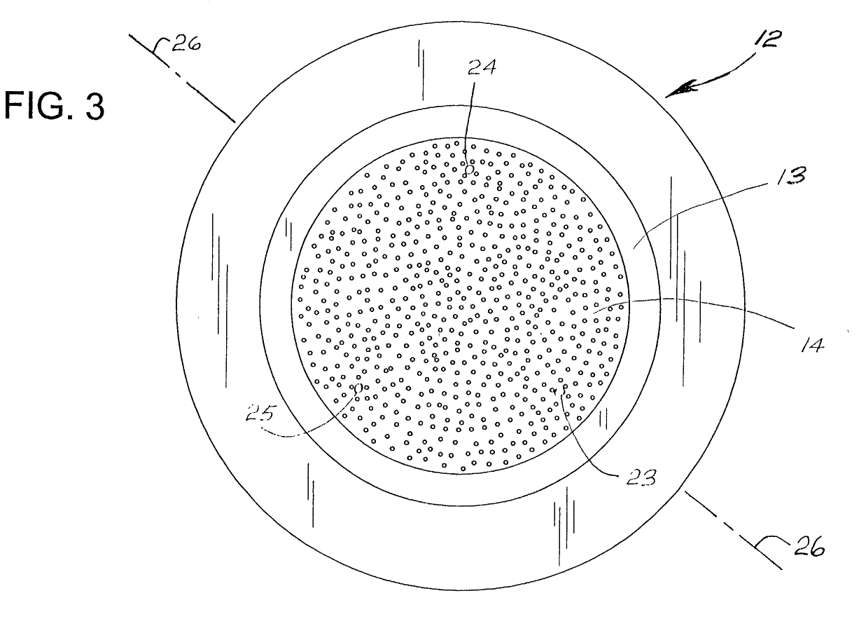

Referring now to FIG. 2 there is shown a cross sectional view of a perforated susceptor 12. The perforated susceptor 12 that has an inner annular ledge 13 which is capable of supporting a silicon wafer substrate 4 which has a front surface 3 and a back surface 5. The perforated susceptor 12 has a porous surface 14 with a plurality of holes or openings 15, 16, 17, 18, 19, 20, 21 and 22. Perforated susceptors for use in single wafer reactors with backside robotic handling (e.g, a CENTURA reactor available from Applied Materials) also require wafer lift pin holes 23, 24 and 25 (not shown, see FIG. 3). In contrast, a perforated susceptor for use in the single wafer EPSILON reactor available from ASM does not require lift pin holes. The terms openings and holes may be used interchangeably herein and both refer to the open passageways in the porous surface 14. Porous surface 14 having the openings is located directly below the silicon wafer substrate 4. As used herein, the term “plurality” means two or more holes. Holes 15, 16, 17, 18, 19, 20, 21 and 22 are drilled into perforated susceptor 12 prior to the coating being applied.

Referring now to FIG. 3, there is shown a top view of perforated susceptor 12 having inner annular ledge 13 and porous surface 9 having a plurality of holes. A perforated susceptor for use in a reactor with backside wafer handling also requires wafer lift pin holes 23, 24, and 25 on porous surface 14 to allow lift pins (not shown) below the perforated susceptor 12 to raise and lower silicon wafers onto and off of the perforated susceptor 12 during and after an epitaxial deposition process.

The holes in the porous surface of the perforated susceptor located directly below the silicon wafer preferably have a diameter such that the silicon carbide or glassy carbon coating, if applied to the susceptor after the holes have been drilled into the susceptor, will not substantially block the holes. The openings may be of any size which create areas of temperature nonuniformity across the back surface of the wafer (i.e., hot and cold spots) by varying radiation of the back surface by the heating lamps located below the silicon wafer. The localized temperature nonuniformities lead to non-uniform epitaxial silicon growth on the front surface of the silicon wafer. The variation in the temperature cannot currently be measured, however, based on the measured nanotopography and the known temperature dependence of epitaxial growth rates, it is presently believed that the temperature difference is subtle, e.g., about ±1° C. to about ±10° C. from the measurable nominal wafer temperature. Preferably the holes are drilled about normal to the base of the susceptor; holes drilled into the susceptor at a sufficiently oblique angle may prevent the direct irradiation of the back surface by the lower heater and reduce or prevent the formation of hot or cold spots.

It will be recognized by one skilled in the art that the openings, generally referred to as holes throughout, could be squares, slots, diamond shapes or any other shapes. For ease of manufacture, the openings in the porous surface of the perforated susceptor are preferably circular. The shapes of the openings determine the general shapes of nanotopographic artifacts footprints created by the epitaxial deposition process. For example, an artifact above a circular opening will have a generally circular foot print and will extend above or below nominal epitaxial layer thickness in a generally conical or frusto-conical shape. The conical or frusto-conical shape is due to the fact that the variation of the localized temperature nonuniformity is typically greatest at the point directly above the center of the opening(s) in the perforated susceptor. The conical or frusto-conical shape of the artifact provides a change in the slope of the epitaxial layer which enhances the accuracy of the nanotopography measured using laser scanning measuring devices.

The lateral size of the nanotopographic artifacts is determined by the size of the openings in the susceptor. Preferably, the size of the openings correspond to the size of the typical area measured to determine nanotopography (e.g., 0.5 mm×0.5 mm, 2 mm×2 mm or 10 mm×10 mm). For example, the openings preferably have a width of about 0.1 mm to about 20 mm and more preferably a width of about 0.5 mm to about 10 mm. The width of the openings is defined as the smallest distance between two corners of the opening or the diameter if the opening is a circle. Preferably, the openings are circles, thus a localized area of temperature nonuniformity is preferably about 0.008 mm² to about 315 mm² and more preferably about 0.2 mm² to about 80 mm².

The holes are spaced on the perforated susceptor to allow localized temperature nonuniformities (i.e., if the holes are spaced too closely together, localized temperature nonuniformity may be minimized and significant nanotopographic artifacts may not be grown). Spacing the holes of the perforated susceptor between about 0.5 mm and about 40 mm apart, more preferably between about 2 mm and about 20 mm apart, and most preferably between about 6 mm and about 15 mm apart allows for sufficient localized areas of temperature nonuniformity. Preferably, the total percentage of open area on the perforated surface of the susceptor is between about 0.5% and about 4% of the total surface area of the perforated surface, more preferably between about 1% and about 3% of the total surface area of the perforated surface. The perforated surface of the susceptor preferably has a density of between about 0.2 holes/cm² and about 4 holes/cm², more preferably between about 0.8 holes/cm² and about 1.75 holes/cm². Density as used herein means either a uniform or non-uniform density.

Several techniques may be used to control the height and/or pattern, of the nanotopographic artifacts created by the epitaxial deposition process. For example, the ratio of the power supplied to the upper and lower heaters may be adjusted to produce an unbalanced heating of the silicon wafer (e.g., more of the total energy supplied to the wafer substrate may be from the lower heater thereby enhancing the effect of the holes). In epitaxial growth chambers which utilize lift pins to lift the wafer onto and off the perforated susceptor, the variation in the temperature of the wafer surface above lift pin holes may be controlled by the selection of the material used to construct the lift pins. For example, the lift pins may be constructed of SiC or quartz. SiC lift pins tend to decrease the amount of heat directed to the back surface of the wafer, decrease the temperature of the back surface and decrease the deposition rate of the epitaxial silicon. In contrast, quartz lift pins allow significantly more radiation from the lower heater to reach the back surface, increasing the temperature and the deposition rate (compared to SiC lift pins/plugs). Similarly, the height of the nanotopographic artifacts above the openings may be controlled by the use of plugs of different materials to fill the perforations in the susceptor (e.g., quartz and silicon carbide plugs). The height of the nanotopography artifacts may also be controlled by the duration of the epitaxial deposition process; the longer the process the greater the vertical variation in the nanotopographic artifacts.

Thus, by using the perforated susceptor, plugs, lift pins, controlling lamp power, and deposition time, among other things, a silicon wafer metrology standard with both positive (bumps) and negative (dimples) nanotopographic artifacts of varying lateral size, vertical size, shape and density can be produced by epitaxial deposition.

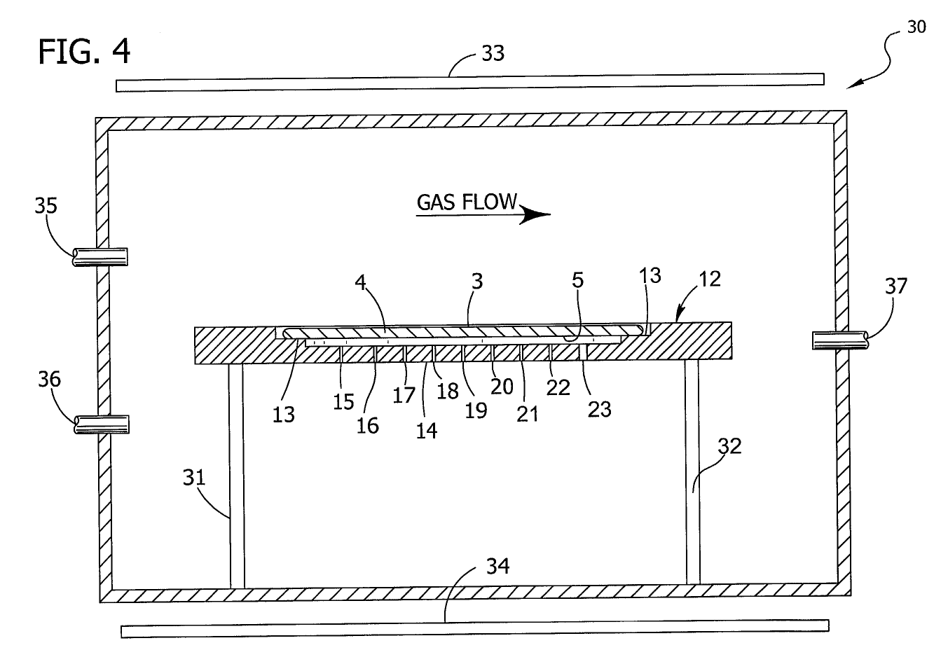

Referring now to FIG. 4, there is shown an epitaxial reaction chamber 30 for use during an epitaxial growth process utilizing the perforated susceptor 12 of the present invention. Perforated susceptor 12 is attached to rotatable supports 31 and 32 and is sized and configured to support silicon wafer substrate 4 on inner annular ledge 13 during an epitaxial deposition process. Silicon wafer substrate 4 is in a spaced relationship with holes 15, 16, 17, 18, 19, 20, 21 and 22 in porous surface 14 in perforated susceptor 12. Lift pin hole 23 allows a lift pin (not shown) access through porous surface 14 of perforated susceptor 12 to silicon wafer substrate 4 such that silicon wafer substrate 4 may be lifted onto and off of perforated susceptor 12 before and after an epitaxial deposition process. Epitaxial deposition chamber 30 also contains heating lamp arrays 33 and 34 located above and below perforated susceptor 12 respectively for heating during an epitaxial deposition process. Gas inlets 35 and 36 allow the introduction of the cleaning gas during the prebake step of the epitaxial deposition process to such that cleaning gas is introduced above and below the silicon wafer substrate 4 to enhance the native oxide removal from the front surface 3 and back surface 5 of silicon wafer substrate 4. During the epitaxial growth step, gas inlet 35 introduces a silicon containing source gas which is flowed above the silicon wafer substrate 4. As indicated in FIG. 4, the gas injected into the epitaxial deposition chamber preferably flows parallel to the front and back surfaces of the silicon wafer (a parallel flow pattern, however is not required). Gases introduced into chamber 30 from gas inlets 35 and 36 are removed from chamber 34 through exhaust port 37.

2. Perforated Susceptor in which the Wafer Rests on the Porous Surface

In an alternative embodiment of the present invention, the perforated susceptor may be sized and configured to allow the silicon wafer to rest directly on the porous surface thus eliminating the inner annular ledge 13 as shown in FIG. 4. Referring now to FIG. 5, there is shown a cross section of a perforated susceptor where the silicon wafer rests directly upon the porous surface. The back surface 5 of silicon wafer substrate 4 sits directly on porous surface 41 of perforated susceptor 40.

3. Perforated Susceptor in which the Wafer Rests on a Concave Porous Surface

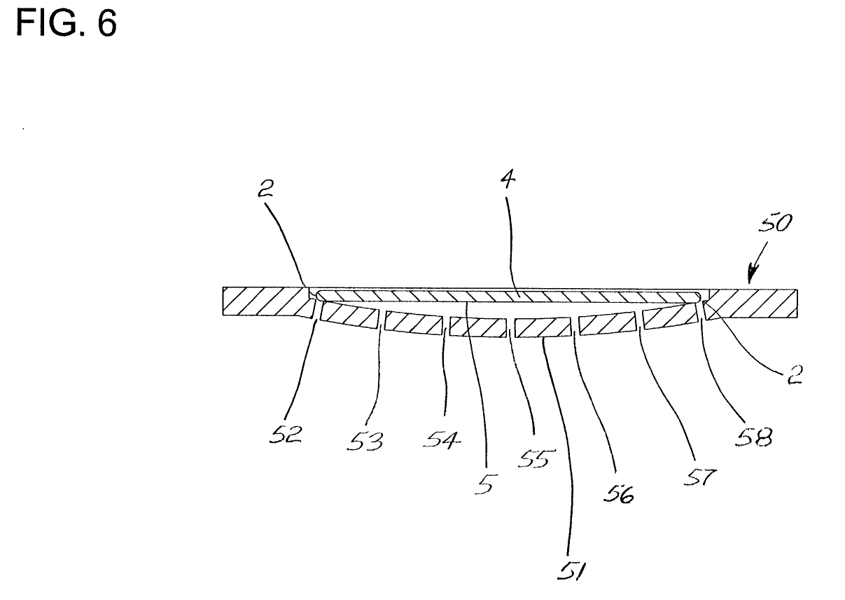

In a further alternative embodiment, the perforated susceptor of the present invention as illustrated in FIG. 5 may be further modified such that porous surface is shaped in a dish shape to allow only the outer edge of the silicon wafer to contact the perforated susceptor. Referring now to FIG. 6, there is shown a cross section of a perforated susceptor 50 where the silicon wafer rests directly on the porous surface 51 of the susceptor 50. Porous surface 51 is shaped like a dish such that the outer edges 2 of silicon wafer substrate 4 are in direct contact with the porous surface 51 and the remainder of back surface 5 of wafer substrate 4 is not in direct contact with porous surface 51. During use, holes 52, 53, 54, 55, 56, 57 and 58 allow direct irradiation of the back surface of the wafer substrate.

D. Metrologoy Standard with Grown-in Nanotopographic Artifacts

Again referring to FIG. 1, the metrology standard 1 comprises an epitaxial layer 10 deposited on the front surface 3 of the wafer substrate 4. The epitaxial layer may be deposited onto the entire wafer, or, alternatively, onto only a portion of the wafer. The nominal thickness of the epitaxial silicon layer is about 0.1 μm to about 200 μm, preferably about 1 μm to about 100 μm, and more preferably about 2 μm to about 30 μm, and still more preferably about 2 μm to about 5 μm.

The epitaxial layer 10 comprises nanotopographical artifacts 60, 61, 62, 63, 64 and 65 grown into the epitaxial layer. The thickness of the epitaxial layer at the position of the epitaxial growth artifacts may be less than nominal thickness and resemble a valley (e.g., artifacts 60, 62 and 64) or greater than the nominal thickness and resemble a hill (e.g., artifacts 61, 63 and 65). The maximum variation from the nominal thickness of an artifact is largely dependent on the localized temperature nonuniformity and the thickness of the epitaxial layer. Experimental results indicate that a localized temperature nonuniformity results in a difference in growth rate of about ±1% to about ±3%. Thus, the vertical variation of the artifacts is about ±1 nm to about ±6,000 nm, preferably about ±10 nm to about ±3,000 nm and still more preferably about ±20 nm to about ±150 nm. For example, an artifact on an epitaxial layer with a nominal thickness of about 5 μm will have a variation is about ±50 nm to about ±150 nm. The horizontal size and shape of the artifacts correspond to the openings in the perforated susceptor and preferably is similar to that of the nanotopography which is typically measured during silicon wafer manufacturing and for which a calibration wafer is desired. For example, the width of the artifacts is preferably about 0.1 mm to about 20 mm and more preferably about 0.5 mm to about 10 mm. The width of the artifacts is defined as the smallest distance (measured at the nominal thickness of the epitaxial layer) between two corners of the artifact or the diameter (measured at the nominal thickness of the epitaxial layer) if the artifact is generally conical. The artifacts are preferably spaced between about 0.5 mm and about 40 mm apart, more preferably between about 2 mm and about 20 mm apart, and most preferably between about 6 mm and about 15 mm apart.

E. Calibration of the Epitaxial Silicon Wafer Metrology Standard

Preferably, epitaxial silicon wafer metrology standards of the present invention are themselves calibrated with a stylus profiler such as the DIMENSION VX series Atomic Force Profiler available from Veeco (Santa Barbara, Calif., U.S.A.). Calibrating the epitaxial wafer metrology standard with the stylus profiler allows the epitaxial wafer to be used as an absolute standard for calibrating a laser surface scanner rather than as a relative standard. Typically, a stylus profiler can measure height, or vertical, variation from about 1 nm to about 6000 nm over a lateral distance of about 5 nm to about 100 mm. Typically, the nanotopography of a wafer is measured in a horizontal line for a distance of about 0.5 mm to about 10 mm. The distance measure is typically not greater than about 10 mm because the variation in height due to nanotopography is eclipsed by the waviness of the wafer substrate. To produce a nanotopographic plot for an area, multiple adjacent lines are scanned with the stylus.

After calibration, the metrology standard may be characterized by its nanotopography. For example, the nanotopography of the metrology standard for a 0.5 mm×0.5 mm area of the surface is preferably about 10 nm to about 30 nm. In a further embodiment of the present invention, the nanotopography of the surface of the metrology standard for a 2 mm×2 mm area of the surface is preferably 10 nm to about 50 nm. In a further embodiment of the present invention, the nanotopography of the surface of the metrology standard for a 10 mm×10 mm area of the surface is preferably 10 nm to about 100 nm.

### F. Examples

Several experiments have been performed to evaluate the method of calibrating a laser nanotopography scanner of the present invention. For example, epitaxial layers with a nominal thickness of about 3 μm were deposited on 200 mm diameter wafer substrates using three different embodiments of the perforated susceptor with varying hole size, spacing and density. Each embodiment had approximately equidistant holes drilled perpendicularly through the bottom to form a cylindrical pattern of holes with a radius of about 95 millimeters. The number and size of the holes was varied as follows: perforated susceptor A comprised 274 holes having a diameter of about 1.32 mm (hole density of about 0.95 holes/cm²) ; perforated susceptor B comprised 548 holes having a diameter of about 1.32 mm (hole density of about 1.95 holes/cm²); perforated susceptor C comprised 274 holes having a diameter of about 1.02 mm (hole density of about 0.95 holes/cm²). Each embodiment also had three lift pin holes with a diameter of about 8 mm, drilled at approximately 90 mm from the center of the susceptor and spaced about 120° apart. Silicon epitaxial layers were grown on several silicon wafer substrates using the foregoing perforated susceptors. Epitaxial wafers produced using susceptor C, the susceptor with the smaller diameter holes, had significantly less nanotopography. Specifically, wafers with about a 3 μm thick epitaxial layer grown using susceptors A and B exhibited a nanotopography on the surface directly above the holes in the center of the susceptor of about 20 nm and wafers produced using susceptor C exhibited a nanotopography of about 10 nm or less.

Additional experiments were performed to evaluate the relationship between lift pin material and the power supplied to the bottom heater of the epitaxial reaction chamber. For quartz and silicon carbide lift pins, the nanotopography of the epitaxial layer directly above a lift pin hole in a susceptor (i.e., pinmark height) was measured as a function of the percentage of total power supplied to the lower heater. The values in Table 1 are for a quartz lift pin and the values in Table 2 are for a silicon carbide lift pin.

TABLE 1
Quartz Lift Pin

| | |
|---|---|
| Percentage of total power | Approximate Pinmark Height |
| supplied to the lower heater | (nm) |

| | |
|---|---|
| 45 | 20 to 30 |
| 50 | 5 to 15 |
| 55 | -10 to -5 |
| 60 | -20 to -15 |

TABLE 2
Silicon Carbide Lift Pin

| Percentage of total power | | Approximate Pinmark Height |
|---|---|---|
| supplied to the lower heater | | (nm) |
| | 40 | 15 to 20 |
| | 45 | -15 to -10 |
| | 50 | -25 to -20 |
| | 55 | -40 to -30 |
| | 60 | -60 to -40 |

In view of the above, it will be seen that the several objects of the invention are achieved. As various changes could be made in the above-described perforated susceptor without departing from the scope of the invention, it is intended that all matter contained in the above description be interpreted as illustrative and not in a limiting sense.

What is claimed is:

1. A method of calibrating a laser scanning nanotopography measuring device, the method comprising:
growing an epitaxial silicon layer on a front surface of a silicon wafer substrate having a localized temperature nonuniformity on the front surface of the silicon wafer to create a nanotopographic artifact located at the localized temperature nonuniformity; and
measuring the nanotopography of the nanotopographic artifact with the laser scanning nanotopography measuring device to calibrate the laser scanning nanotopography measuring device.

2. The method as set forth in claim 1 comprising measuring the nanotopography of the nanotopographic artifact with a stylus profiler so that the laser scanning nanotopography measuring device is calibrated against an absolute standard.

3. The method as set forth in claim 1 wherein the localized temperature nonuniformity is from about ±1° C. to about ±10° C.

4. The method as set forth in claim 3 wherein the epitaxial silicon layer is grown of the front surface of the silicon wafer having a plurality of localized temperature nonuniformities to create a plurality of nanotopographic artifacts.

5. The method as set forth in claim 4 wherein the epitaxial layer has a nominal thickness between about 0.1 μm and about 200 μm.

6. The method as set forth in claim 4 wherein the epitaxial layer has a nominal thickness between about 1 μm and about 100 μm.

7. The method as set forth in claim 4 wherein the epitaxial layer has a nominal thickness between about 2 μm and about 30 μm.

8. The method as set forth in claim 4 wherein the epitaxial layer has a nominal thickness between about 2 μm and 5μm.

9. The method as set forth in claim 4 wherein the nanotopography of the nanotopographic artifacts is about ±1 nm to about ±6,000 nm.

10. The method as set forth in claim 4 wherein the nanotopography of the nanotopographic artifacts is about ±10 nm to about ±3,000 nm.

11. The method as set forth in claim 8 wherein the nanotopography of the nanotopographic artifacts is about ±20 nm to about ±150 nm.

12. The method as set forth in claim 11 wherein the nanotopographic artifacts are between about 0.1 mm and about 20 mm wide.

13. The method as set forth in claim 11 wherein the nanotopographic artifacts are between about 0.5 mm and about 10 mm wide.

14. The method as set forth in claim 11 wherein the nanotopographic artifacts are between about 0.5 mm and about 40 mm apart.

15. The method as set forth in claim 11 wherein the nanotopographic artifacts are between about 2 mm and about 20 mm apart.

16. The method as set forth in claim 11 wherein the nanotopographic artifacts are between about 6 mm and about 15 mm apart.

17. A method of calibrating a laser scanning nanotopography measuring device, the method comprising:
placing a silicon wafer substrate on a perforated susceptor in a chemical vapor deposition chamber, the silicon wafer substrate having a front surface and a back surface, the chemical vapor deposition chamber comprising an upper heater above the front surface of the silicon wafer substrate and a lower heater below the back surface of the silicon wafer substrate, the perforated susceptor having a surface with an opening that allows direct radiation of the back surface of the silicon wafer substrate by the lower heater, the surface being in a generally parallel opposed relationship with the silicon wafer substrate;
growing an epitaxial layer of silicon on the front surface of the silicon wafer substrate, the epitaxial silicon layer being characterized by having a nominal thickness over the front surface of the epitaxial silicon wafer substrate and a nanotopographic artifact grown into the epitaxial silicon layer above the opening in the perforated susceptor; and
measuring the nanotopography of the nanotopographic artifact grown into the epitaxial silicon layer with the laser scanning nanotopography measuring device to calibrate the laser scanning nanotopography measuring device.

18. The method as set forth in claim 17 comprising measuring the nanotopography of at least one nanotopographic artifact with a stylus profiler so that the laser scanning nanotopography measuring device is calibrated against an absolute standard.

19. The method as set forth in claim 17 wherein the surface of the susceptor comprises a plurality of openings and the epitaxial silicon layer comprises a plurality of nanotopographic artifacts.

20. The method as set forth in claim 19 wherein the silicon wafer substrate is supported by an inner annular ledge of the perforated susceptor.

21. The method as set forth in claim 19 wherein substantially the entire back surface of the silicon wafer rests directly on the porous surface.

22. The method as set forth in claim 19 wherein only the outer edge of the silicon wafer rests directly on the porous surface.

23. The method as set forth in claim 19 wherein the perforated susceptor has lift pin holes in the perforated surface to allow lift pins to pass through the susceptor.

24. The method as set forth in claim 19 wherein the porous surface has a density of openings between about 0.2 openings/cm² and about 4 openings/cm².

25. The method as set forth in claim 19 wherein the porous surface has between about 0.8 openings/cm² and about 1.75 openings/cm².

26. The method as set forth in claim 19 wherein the openings have a diameter of between about 0.1 mm and about 20 mm.

27. The method as set forth in claim 19 wherein the openings have a diameter of between about 0.5 mm and about 10 mm.

28. The method as set forth in claim 19 wherein the openings are spaced between about 2 mm and about 20 mm apart.

29. The method as set forth in claim 19 wherein the openings are spaced between about 6 mm and about 15 mm apart.

30. The method as set forth in claim 19 wherein the total percentage of open area on the surface is between about 0.5% and about 4%.

31. The method as set forth in claim 19 wherein the total percentage of open area on the surface is between about 1% and about 3%.

32. The method as set forth in claim 17 wherein the epitaxial silicon layer is grown at a rate of about 3.5 μm/min to about 4.0 μm/min.

33. The method as set forth in claim 17 wherein the nominal thickness of the epitaxial layer is about 0.1 μm and about 200 μm.

34. The method as set forth in claim 17 wherein the nominal thickness of the epitaxial layer is about 1 μm and about 100 μm.

35. The method as set forth in claim 17 wherein the nominal thickness of the epitaxial layer is about 2 μm and about 30 μm.

36. The method as set forth in claim 17 wherein the nominal thickness of the epitaxial layer is about 2 μm and about 30 μm.

37. The method as set forth in claim 32 wherein during the growth of the epitaxial layer, the area of the front surface of the silicon wafer substrate above the opening in the porous surface of the perforated susceptor corresponds to a localized temperature nonuniformity that results in a variation in the growth rate of the epitaxial silicon layer of about ±1% to about ±3%.

38. The method as set forth in claim 37 wherein the localized temperature nonuniformity is from about ±1° C. to about ±10° C.

39. The method as set forth in claim 37 wherein the nanotopography of the nanotopographic artifacts is about ±1 nm to about ±6,000 nm.

40. The method as set forth in claim 37 wherein the nanotopography of the nanotopographic artifacts is about ±10 nm to about ±3,000 nm.

41. The method as set forth in claim 37 wherein the nanotopography of the nanotopographic artifacts is about ±20 nm to about ±150 nm.

42. The method as set forth in claim 19 wherein the perforated susceptor comprises graphite a silicon carbide layer or a glassy carbon layer covering the graphite.

43. The method as set forth in claim 42 wherein at least one of the openings is filled with a plug that transmits a different amount of energy to the back surface of the silicon wafer substrate than the perforated susceptor.

44. The method as set forth in claim 42 wherein at least one of the openings is filled with a quartz plug.

45. The method as set forth in claim 42 wherein at least one of the openings is filled with a silicon carbide plug.

46. The method as set forth in claim 17 wherein the power supplied to the upper heater and the lower heater is adjusted to control the size of the nanotopographic artifact.

47. The method as set forth in claim 46 wherein the power supplied to the lower heater is adjusted between about 40% to about 60% of the of the total power supplied to the upper heater and the lower heater.

48. A method of measuring the nanotopography of a semiconductor substrate versus that of a metrology standard, the method comprising:
measuring the nanotopography of the metrology standard with a laser scanner nanotopography measuring device, the metrology standard comprising a silicon wafer substrate having a front surface and a back surface and an epitaxial silicon layer grown on the front surface of the silicon wafer substrate, the epitaxial silicon layer is characterized by a nominal thickness and comprises a grown-in nanotopographic artifact characterized by a vertical variation from the nominal thickness ranging from about ±1 nm to about ±6,000 nm and a width of between about 0.1 mm to about 20 mm;
measuring the nanotopography of a portion of a surface of the semiconductor substrate with the laser scanner nanotopography measuring device; and
comparing the nanotopography of the portion of the surface of the semiconductor substrate with the nanotopography of the nanotopographic artifact of the metrology standard.

49. The method as set forth in claim 48 wherein the nominal thickness of the epitaxial layer grown on the metrology standard is between about 0.1 μm and about 200 μm.

50. The method as set forth in claim 48 wherein the nominal thickness of the epitaxial layer grown on the metrology standard is between about 1 μm and about 100 μm.

51. The method as set forth in claim 48 wherein the nominal thickness of the epitaxial layer grown on the metrology standard is between about 2 μm and about 30 μm.

52. The method as set forth in claim 48 wherein the nominal thickness of the epitaxial layer grown on the metrology standard is between about 2 μm and 5 μm.

53. The method as set forth in claim 48 wherein the grown-in nanotopographic artifact has a vertical variation from the nominal thickness ranging from about ±10 nm to about ±3,000 nm.

54. The method as set forth in claim 48 wherein the grown-in nanotopographic artifact has a vertical variation from the nominal thickness ranging from about ±20 nm to about ±150 nm.

55. The method as set forth in claim 48 wherein the width of the grown-in nanotopographic artifact is between about 0.5 mm to about 10 mm.

56. The method as set forth in claim 48 wherein the grown-in nanotopographic artifact has a generally conical shape.

57. The method as set forth in claim 48 wherein the grown-in nanotopographic artifact has a generally frusto-conical shape.

58. The method as set forth in claim 48 wherein the epitaxial layer of the metrology standard comprises a plurality of grown-in nanotopographic artifacts.

59. The method as set forth in claim 58 wherein the grown-in nanotopographic artifacts are between about 0.5 mm and about 40 mm apart.

60. The method as set forth in claim 58 wherein the grown-in nanotopographic artifacts are between about 2 mm and about 20 mm apart.

61. The method as set forth in claim 58 wherein the grown-in nanotopographic artifacts are between about 6 mm and about 15 mm apart.
